(19) United States
(12) Patent Application Publication
(10) Pub. No.: US 2023/0197399 A1
(43) Pub. Date: Jun. 22, 2023

(54) ELECTRON MICROSCOPE, ELECTRON SOURCE FOR ELECTRON MICROSCOPE, AND METHODS OF OPERATING AN ELECTRON MICROSCOPE

(71) Applicant: ICT Integrated Circuit Testing Gesellschaft für Halbleiterprüftechnik mbH, Heimstetten (DE)

(72) Inventor: Pavel Adamec, Haar (DE)

(73) Assignee: ICT Integrated Circuit Testing Gesellschaft für Halbleiterprüftechnik mbH, Heimstetten (DE)

(21) Appl. No.: 17/557,700

(22) Filed: Dec. 21, 2021

(51) Int. Cl. H01J 37/073; H01J 37/26; H01J 37/14

(52) U.S. Cl. CPC H01J 37/073; H01J 37/26; H01J 37/14

(57) ABSTRACT

An electron microscope (100) is described. The electron microscope comprises an electron source (110) for generating an electron beam, a condenser lens (130) for collimating the electron beam downstream of the electron source, and an objective lens (140) for focusing the electron beam onto a specimen (16). The electron source comprises a cold field emitter with an emission tip (112), an extractor electrode (114) for extracting the electron beam (105) from the cold field emitter for propagation along an optical axis (A), the extractor electrode having a first opening (115) configured as a first beam limiting aperture, a first cleaning arrangement (121) for cleaning the emission tip (112) by heating the emission tip, and a second cleaning arrangement (122) for cleaning the extractor electrode (114) by heating the extractor electrode. Further described is a method of operating such an electron microscope.

### TECHNICAL FIELD

Embodiments described herein relate to an electron apparatus, particularly an electron microscope, and more particularly to a scanning electron microscope (SEM), for inspection or imaging system applications, testing system applications, lithography system applications or the like. Embodiments described herein specifically relate to an electron microscope with a cold field emitter that provides a high-brightness electron beam for high-resolution and high-throughput applications. More specifically, a high throughput wafer inspection SEM is described. Embodiments described herein also relate to an electron source for an electron microscope, as well as to methods of operating an electron microscope.

### BACKGROUND

Electron microscopes have many functions in a plurality of industrial fields including, but not limited to, inspection or imaging of semiconductor substrates, wafers and other specimens, critical dimensioning, defect review, exposure systems for lithography, detector arrangements, and testing systems. There is a high demand for structuring, testing, inspecting and imaging specimens on the micrometer and nanometer scale. Electron microscopes offer superior spatial resolution compared to, e.g., photon beams, enabling high-resolution imaging and inspection.

An electron microscope includes an electron source, or “electron gun”, that generates the electron beam that impinges on the specimen. Different types of electron sources are known, including thermal field emitters, Schottky emitters, thermally assisted field emitters, and cold field emitters. A cold field emitter (CFE) includes an emission tip that is cold (=unheated) during operation, which emits electrons by applying a high electrostatic field between the emission tip and an extractor electrode. While thermal field emitters can typically provide high-current electron beams, cold field emitters have the potential to provide a high-brightness electron beam probe that is suitable for achieving high resolutions.

However, CFEs are particularly sensitive with respect to contamination and should therefore be operated under extremely good vacuum conditions in an evacuated gun housing, specifically under ultra-high vacuum conditions. Still, unwanted ions, ionized molecules or other contamination particles can be present in the evacuated gun housing. For example, charged contamination particles can be accelerated toward the emitter, such that the emission tip can be mechanically deformed or can be otherwise negatively affected. Further, the accumulation of particles on an emitter surface or on other surfaces of the electron source can introduce noise and other beam instabilities.

Specifically, contamination particles in the region of the electron gun may lead to an unstable or noisy electron beam, e.g. to a varying beam current or a variable beam profile. Therefore, the vacuum conditions within an electron microscope, and specifically within the gun housing that houses the CFE, are critical.

In view of the above, it would be beneficial to improve the beam stability of electron beams in electron microscopes and to reduce the amount of contamination particles within the gun housing. Specifically, it would be beneficial to provide a compact electron microscope with a CFE electron gun that emits a high-brightness electron beam with an improved stability which can further improve the obtainable resolution and throughput. Further, it would be beneficial to provide a method of operating an electron microscope such as to provide a high-brightness electron beam with an improved beam stability.

### SUMMARY

In light of the above, electron microscopes, electron sources, and methods of operating an electron microscope according to the independent claims are provided. Further aspects, advantages, and features are apparent from the dependent claims, the description, and the accompanying drawings.

According to one aspect, an electron microscope is provided. The electron microscope includes an electron source, a condenser lens, and an objective lens. The electron source includes a cold field emitter (CFE) with an emission tip; an extractor electrode for extracting an electron beam from the cold field emitter for propagation along an optical axis, the extractor electrode having a first opening configured as a first beam limiting aperture; a first cleaning arrangement for cleaning the emission tip by heating the emission tip; and a second cleaning arrangement for cleaning the extractor electrode by heating the extractor electrode. The condenser lens is for collimating the electron beam downstream of the electron source, and the objective lens is for focusing the electron beam onto a specimen.

According to one aspect, an electron source for an electron microscope as described herein is provided. The electron source includes a cold field emitter (CFE) with an emission tip; an extractor electrode for extracting an electron beam from the cold field emitter for propagation along an optical axis; a first cleaning arrangement for cleaning the emission tip by heating the emission tip; and a second cleaning arrangement for cleaning the extractor electrode by heating the extractor electrode. The electron source can be used in an electron microscope as described herein, or in another electron apparatus that uses a high-brightness electron gun.

According to another aspect, a method of operating an electron microscope having an electron source with a cold field emitter is provided. The method includes, in a first cleaning mode, cleaning an emission tip of the cold field emitter by heating the emission tip; in a second cleaning mode, cleaning an extractor electrode of the electron source by heating the extractor electrode; and, in an operation mode, extracting an electron beam from the cold field emitter for propagation along an optical axis, the electron beam being shaped by a first opening that may be provided in the extractor electrode; collimating the electron beam with a condenser lens; and focusing the electron beam onto a specimen with an objective lens.

According to another aspect, a method of cleaning an electron source with a cold field emitter is provided. The method includes, in a first cleaning mode, cleaning an emission tip of the cold field emitter by heating the emission tip; and, in a second cleaning mode, cleaning an extractor electrode of the electron source by heating the extractor electrode. After cleaning in the first and second cleaning modes, the electron source can be operated for generating an electron beam, e.g. in an electron microscope as described herein.

A cleaning controller may be provided for setting the electron microscope in the first cleaning mode, e.g. after predetermined intervals of operating the electron microscope, and/or for setting the electron microscope in the second cleaning mode, e.g. after flooding of the gun housing with air, or for improving the beam stability.

Embodiments are also directed at apparatuses for carrying out the disclosed methods and include apparatus parts for performing each described method feature. The method features may be performed by way of hardware components, a computer programmed by appropriate software, by any combination of the two or in any other manner. Furthermore, embodiments are also directed at methods of manufacturing the described apparatuses, methods of operating the described apparatuses, and methods of inspecting or imaging a specimen with the described electron microscopes. It includes method features for carrying out every function of the apparatus.

### BRIEF DESCRIPTION OF THE DRAWINGS

So that the manner in which the above recited features of the present disclosure can be understood in detail, a more particular description, briefly summarized above, may be had by reference to embodiments. The accompanying drawings relate to embodiments of the disclosure and are described in the following:

FIG. 1 is a schematic sectional view of an electron microscope with an electron source including a cold field emitter according to embodiments described herein;

FIG. 2 is a schematic sectional view of an electron microscope with an electron source including a cold field emitter according to embodiments described herein; and

FIG. 3 is a flow chart illustrating a method of operating an electron microscope according to embodiments described herein.

### DETAILED DESCRIPTION OF EMBODIMENTS

Reference will now be made in detail to the various embodiments, one or more examples of which are illustrated in the figures. Within the following description, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

In an electron microscope, an electron beam is directed onto a specimen that is placed on a sample stage. Specifically, the electron beam is focused onto a surface of the specimen that is to be inspected. Upon impingement of the electrons on the specimen, signal particles are emitted, scattered and/or reflected by the specimen. The signal particles particularly encompass secondary electrons and/or backscattered electrons, specifically both secondary electrons (SEs) and backscattered electrons (BSEs). The signal electrons are detected by one or more electron detectors, and the respective detector signals may be processed or analyzed by a processor for inspecting or imaging the specimen. For example, an image of at least a portion of the specimen can be generated based on the signal electrons, or the specimen can be inspected for determining defects, for checking the quality of deposited structures, and/or for conducting critical dimension (CD) measurements.

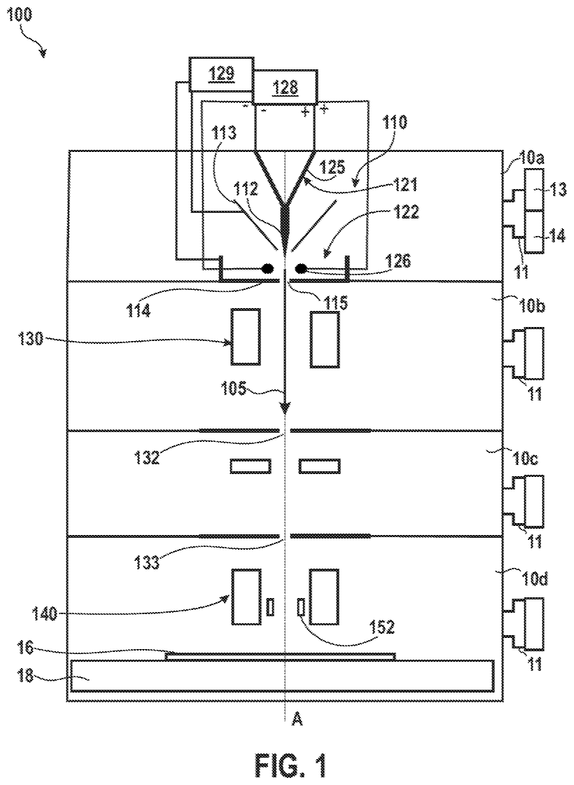

FIG. 1 is a schematic view of an electron microscope 100 according to embodiments described herein. The electron microscope 100 includes an electron source 110 configured for generating an electron beam 105 that can be used for, e.g., inspection or imaging applications. The electron microscope 100 further includes a condenser lens 130 configured to reduce the divergence of the electron beam (referred to herein as “collimation”), particularly for providing an electron beam that is only slightly divergent, parallel or converging, and that propagates along an optical axis A toward an objective lens 140 for being focused onto a specimen 16. Specifically, the combined action of the condenser lens 130 and the objective lens 140 may focus the electron beam 105 on a surface of the specimen 16 that may be placed on a sample stage 18. The sample stage 18 may be movable.

According to the embodiments described herein, the electron source 110 comprises a cold field emitter (CFE) with an emission tip 112. The CFE is configured to emit the electron beam by cold field emission. A cold field emitter is particularly sensitive to contamination in the gun housing where the cold field emitter is positioned, such that an ultra-high vacuum is beneficially provided in the gun housing. The gun housing that houses the CFE is also referred to herein as a “first vacuum region 10a” that may be arranged upstream of one or more further vacuum regions (e.g., second vacuum region 10b and third vacuum region 10c) that allow differential pumping.

In some embodiments, the cold field emitter (CFE) may have a tungsten tip. In some implementations, which can be combined with other embodiments, the emission tip 112 consists of a crystal that is etched to a sharp tip, particularly a sharp tip having a final radius (tip radius) in the range of 10 nm to 500 nm, particularly 200 nm or less, more particularly 100 nm or less. The crystal may typically be a tungsten crystal, in particular a tungsten crystal oriented with (3,1,0)-crystallographic orientation along the optical axis A, more particularly a tungsten single crystal. If the emission tip has a sharp tip with a small radius, the crystal area from which electron emission takes place is reduced, which improves the brightness of the generated electron beam.

The electron source 110 further includes an extractor electrode 114 for extracting the electron beam 105 for propagation along the optical axis A. The extractor electrode 114 has a first opening 115 that may be configured as a beam limiting opening. Specifically, the first opening 115 may have a size configured to pass electrons propagating close to the optical axis A (“axial electrons”) and to block electrons farther away from the optical axis A, such that a beam profile in accordance with the size and shape of the first opening 115 can be formed.

In some embodiments, the first opening 115 may be a circular opening configured to generate a rotationally symmetric beam profile of the electron beam 105. In some embodiments, which can be combined with other embodiments described herein, the first opening 115 may have a diameter of 100 μm or less, particularly 50 μm or less, or even 20 μm or less. The first opening 115, having a small dimension, reduces the size of the electron beam propagating toward the extractor electrode 114 and thus suppresses a loss of brightness due to electron-electron interactions.

During operation of the electron microscope, the extractor electrode 114 may be set on a positive potential relative to the emission tip 112, e.g. with a potential difference in the range of several kilovolts (kV) between the emission tip 112 and the extractor electrode 114, such as 5 kV or more. The potential difference is large enough to generate an electric field at the surface of the emission tip 112 to cause cold field emission. The extraction main mechanism of a cold field emitter is tunneling through the surface potential barrier of the tip surface. This can be controlled by the extraction field of the extractor electrode.

In some embodiments, a distance between the emission tip 112 and the extractor electrode 114 is 0.1 mm or more and 3 mm or less, particularly 1 mm or less. A small distance leads to a quick acceleration of the emitted electrons toward the condenser lens 130, such that a loss of brightness due to electron-electron interaction can be reduced.

The electron microscope 100 includes several mechanisms for improving the vacuum conditions and for reducing contamination in the first vacuum region 10a where the cold field emitter is placed. Excellent vacuum conditions and reduced contamination in the gun housing improve the beam stability and the brightness of the electron beam 105 which is particularly beneficial if a CFE is used. A high-brightness electron beam is particularly beneficial in a high-throughput EBI system.

The electron microscope 100 includes a first cleaning arrangement 121 for cleaning the emission tip 112 of the CFE by heating the emission tip 112 and a second cleaning arrangement 122 for cleaning the extractor electrode 114 by heating the extractor electrode 114.

The electron microscope 100 may switch into a first cleaning mode for cleaning the emission tip 112 with the first cleaning arrangement 121 by heating the emission tip 112, particularly to a temperature of 1500° C. or more. The electron microscope 100 may switch into a second cleaning mode for cleaning the extractor electrode 114 with the second cleaning arrangement 122 by heating the extractor electrode 114, particularly to a temperature of 500° C. or more. In some embodiments, the first cleaning arrangement 121 may include a first heater, particularly a resistive heater that may be in thermal contact with the emission tip 112, for heating the emission tip, particularly by allowing an electric current to flow through the first heater. By allowing the electric current to flow through the first heater, the first heater may be heated together with the emission tip 112 that is in thermal contact therewith. Alternatively or additionally, the second cleaning arrangement 122 may include a second heater, particularly a heating wire 126 (also referred to herein as a “cleaning emitter” due to the emission of thermal electrons) that may be arranged in close proximity to the extractor electrode 114, for heating the extractor electrode 114, particularly by allowing an electric current to flow through the second heater.

Since the electrons are emitted from a very small surface portion of the emission tip in a cold field emitter during operation, the emission is very sensitive to even a single or a few contamination atoms on the emitting surface. The atoms that can adsorb on the emitting surface may originate from surrounding surfaces, such as from the extractor electrode where desorption can be stimulated by electrons of the electron beam that impinge on the extractor electrode, e.g. in the area that surrounds the first opening 115. Therefore, a high cleanliness not only of the emission tip, but also of the extractor electrode is beneficial.

The second cleaning arrangement 122 may be operated by heating a heating wire 126 of the second cleaning arrangement 122 that is positioned adjacent to the extractor electrode 114, such that electrons are thermally emitted by the heating wire and impinge on the surface of the extractor electrode, heating up the extractor electrode. The heating wire may be heated to a temperature of 1500° C. or more, particularly 2000° C. or more, which may provide a strong thermal emission of electrons by the heating wire. The thermal electrons can desorb molecules and atoms that may be present on the surface of the extractor electrode even at high vacuum conditions. In other words, the extractor electrode may be cleaned by electron stimulated desorption caused by thermal electrons emitted by the heated heating wire. The thermal electrons may be accelerated toward the extractor electrode, e.g. by applying a respective potential difference between the extractor electrode and another electrode, e.g. the suppressor electrode and/or the emission tip. Further, the thermal electrons impinging on the extractor electrode may heat up the extractor electrode, such that the extractor electrode is also cleaned by thermal outgassing. In some embodiments, the second cleaning arrangement 122 is configured to clean the extractor electrode by two cleaning mechanisms: (1) thermal outgassing and (2) electron stimulated desorption.

Optionally, a suppressor electrode 113 may be further arranged in the gun housing, e.g. partially between the emission tip 112 and the heating wire 126. In the second cleaning mode (i.e., during heating with the second cleaning arrangement 122), the suppressor electrode 113 can be set on a predetermined electrical potential that is suitable for deflecting the electrons emitted by the heating wire 126 toward the extractor electrode 114 and/or away from the emission tip 112. This may reduce a risk of deforming the emission tip 112 by the thermal electrons of the second cleaning arrangement 122 and/or may help in directing the thermal electrons toward the area of the extractor electrode that is to be cleaned, particularly by electron stimulated desorption.

In some embodiments, a voltage source 129 is provided for connecting any one or more of the extractor electrode 114, the suppressor electrode 113, and/or the emission tip 112 to a predetermined electric potential, e.g. during cleaning and/or during operation.

In some embodiments, the heating wire 126 of the second cleaning arrangement 122 may be positioned in close proximity to the extractor electrode 114, particularly at a distance of 2 mm or less, or even 1 mm or less, from the extractor electrode 114. In particular, the heating wire 126 may be positioned close to an area of the extractor electrode 114 that surrounds the first opening 115 which is typically hit by electrons of the electron beam 105 during the operation of the electron microscope.

In some implementations, the second cleaning arrangement 122 may include a heating wire or a heating filament through which an electric current can sent for heating. Specifically, a first end of the heating wire 126 may be connected to a first output terminal of a current source and a second end of the heating wire 126 may be connected to a second output terminal of the current source that is set on a different potential. The heating wire 126 or heating filament may at least partially surround the first opening 115 of the extractor electrode 114 (e.g. by a circumferential angle of 180° or more, or even 270° or more), such that the edge of the first opening 115 can be heated in a targeted way by the second cleaning arrangement 122. For example, the heating wire 126 may extend in an annular or circular shape around the first opening 115.

In some embodiments, which can be combined with other embodiments described herein, the second heater of the second cleaning arrangement 122, particularly the heating wire 126, may include or may be made of tungsten or tantalum, particularly of tantalum.

Tantalum provides particularly convincing cleaning results if used as the second heater for cleaning the extractor electrode, and tantalum is specifically suitable as a thermal electron emitter in ultra-high vacuum environments. Accordingly, in embodiments disclosed herein, without being limited thereto, a tantalum heater is typically used in the second cleaning arrangement 122 that is positioned in close proximity to the extractor electrode 114, particularly in the form of a heating wire that at least partially surrounds the first opening 115.

The electron microscope may further include a cleaning controller 128 configured to allow, in the second cleaning mode, a current to flow through the second heater of the second cleaning arrangement for heating the extractor electrode at least partially to a temperature of at least 500° C., particularly at least 600° C., more particularly to a temperature in a range between 600° C. and 800° C. Specifically, the area of the extractor electrode 114 that surrounds the first opening 115 may be heated by the second cleaning arrangement. In a preceding calibration, the current that flows through the second heater for providing temperatures of the extractor electrode of 500° C. or more, particularly from 600° C. to 800° C., can be identified and stored. When switching to the second cleaning mode, the cleaning controller 128 may then apply the respective current to the second cleaning arrangement 122. The second heater itself, particularly the heating wire 126, may have a temperature of 1500° C. or more, particularly 2000° C. or more, or even 2200° C. or more during the heating.

In some embodiments, which can be combined with other embodiments described herein, the first cleaning arrangement 121 includes a heating filament 125 in thermal contact with the emission tip 112. The emission tip 112 may be bonded to or attached to the heating filament 125. In particular, the heating filament 125 may be a V-shaped heating filament, and the emission tip 112 may be bonded to the kink of the V-shaped heating filament. The two ends of the V-shaped heating filament may be connected to two output terminals of a current source that can be set on different electric potentials for enabling a current flow through the V-shaped heating filament.

In some embodiments, the heating filament 125 is a tungsten filament and/or the emission tip 112 of the CFE that is bonded thereto is a tungsten tip.

When a current flows through the heating filament 125, the heating filament 125 heats up together with the emission tip 112 that is thermally contacted with the heating filament 125. The first cleaning arrangement 121 may be configured to heat the emission tip 112 in the first cleaning mode to a temperature of 1500° C. or more, particularly 2000° C. or more, more particularly 2000 K or more.

The heating of the emission tip 112 via the heating filament 125 can evaporate adsorbed molecules, which cleans the emission tip 112 and helps in providing a more stable electron beam emission. Further, the heating of the emission tip may also shape the emission tip, such that a sharp tip can be provided and/or maintained. Optionally, the extractor electrode 114 may be set on a predetermined electric potential during the heating of the emission tip first cleaning mode, which may avoid or reduce a rounding or flattening of the emission tip during the heating and/or which may facilitate the maintenance of a sharp emission tip.

The electron microscope may include a cleaning controller 128 configured to allow, in the first cleaning mode, a current to flow through the heating filament 125 of the first cleaning arrangement 121 for heating the emission tip 112 to the temperature of at least 1500° C., particularly at least 2000° C. In a preceding calibration stage, the current that flows through the heating filament 125 for achieving temperatures of the emission tip 112 of 2000° C. or more can be identified. When switching to the first cleaning mode, the cleaning controller 128 may then apply the respective current to the first cleaning arrangement 121.

In some embodiments, as is exemplarily shown in FIG. 1, one cleaning controller 128 may provide for allowing, in the first cleaning mode, the current to flow through the heating filament 125 for heating the emission tip and for allowing, in the second cleaning mode, the current to flow through the heating wire 126 for heating the extractor electrode 114. In some embodiments, separate cleaning controllers may be connected to the first and second cleaning arrangements. During the operation of the electron microscope, the emission tip 112 may be set on a predetermined electric potential relative to the extractor electrode 114, e.g. by applying same voltages to both ends of the V-shaped heating filament, such that no current flow and hence no heating of the tip takes place, enabling a cold field emission from the emission tip.

The first cleaning mode may also be referred to as a “flashing mode” because the emission tip is heated to high temperatures over a comparatively short period, for evaporating adsorbed particles and contamination and for ensuring a more stable electron beam. The cleaning controller 128 may be configured for setting the electron microscope 100 in the first cleaning mode before starting the operation of the electron microscope and/or after predetermined time periods of operation, e.g. at regular intervals (such as once an hour) if the electron microscope is operated. A continually clean and sharp emitter tip can be ensured by switching regularly to the first cleaning mode.

Alternatively or additionally, the cleaning controller 128 may be configured for setting the electron microscope in the second cleaning mode before operation of the electron microscope after the gun housing has been ventilated or flooded with air, and/or during maintenance or servicing of the electron microscope, and/or if the electron beam shows undesired instabilities. Accordingly, the interval between two first cleaning modes is typically shorter as compared to the interval between two second cleaning modes.

In some embodiments, which can be combined with other embodiments described herein, a distance between the emission tip 112 and the first opening 115 of the extractor electrode 114 may be 5 mm or less, particularly 3 mm or less, more particularly 1 mm or less, and/or 0.1 mm or more. Accordingly, the electrons emitted by the emission tip 112 are accelerated very quickly and over a short propagation range toward the extractor electrode, which reduces the electron-electron interaction and improves the brightness of the electron beam.

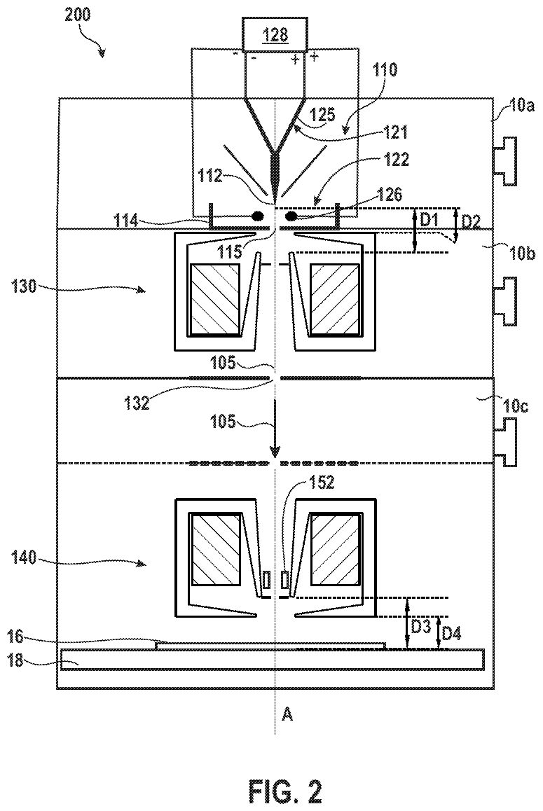

The electron microscope 100 may include an acceleration section for accelerating the electron beam, e.g., to an electron energy of 5 keV or more, wherein the acceleration section is arranged upstream of the condenser lens 130 and/or at least partially overlaps with the condenser lens 130. The electrons may be accelerated toward the extractor electrode 114 that is set on a positive potential relative to the emission tip, and the electrons may optionally be further accelerated toward an anode that may be arranged downstream of the extractor electrode 114, e.g. between the extraction electron and the condenser lens or within the condenser lens (shown in FIG. 2). In some embodiments, the electrons are accelerated to an electron energy of 10 keV or more, 30 keV or more, or even 50 keV or more. A high electron energy within the column can reduce negative effects of electron-electron interactions.

In some embodiments, the electron microscope 100 may include a deceleration section for decelerating the electron beam from the energy of 5 keV or more to a smaller landing energy, wherein the deceleration section may be downstream of or at least partially overlapping with the objective lens 140. For example, the electrons may be decelerated to a landing energy of 3 keV or less, particularly 2 keV or less, or even 1 keV or less, such as 800 eV or less. Electrons with a reduced landing energy are more suitable for interaction with the specimen structures, such that a reduced landing energy may improve the obtainable resolution. For example, a proxy electrode arranged close to the sample stage may brake the electrons before impingement on the specimen, or the specimen may be set on a braking potential.

The signal particles released from the specimen 16 may be accelerated along the deceleration section toward the objective lens and may propagate through the objective lens toward an electron detector (not shown in the figures).

The electron microscope may include the gun housing that is a first vacuum region 10a that can be evacuated with one or more vacuum pumps, particularly to an ultra-high vacuum. The gun housing that houses the electron source 110 is typically positioned upstream of the column of the electron microscope.

The electron microscope may use several so-called differential pumping regions that are separated by a respective differential pumping aperture for improving the vacuum conditions in the gun chamber. Differential pumping regions may be understood as vacuum regions that can be separately pumped by one or more respective vacuum pumps and are separated by a respective gas separation wall for improving the vacuum conditions in the most upstream vacuum region. A differential pumping aperture, i.e. a small opening for the electron beam, may be provided in the gas separation wall, such that the electron beam can propagate from an upstream differential pumping section into a downstream differential pumping section along the optical axis. “Downstream” as used herein may be understood as downstream in the propagation direction of the electron beam along the optical axis A.

In some embodiments, the first opening 115 of the extractor electrode 114 may be arranged to act as a first differential pumping aperture, i.e. as an aperture in a gas separation wall that enables differential pumping between the gun housing and a second vacuum region 10b downstream of the gun housing. When the first opening 115 acts both as a beam limiting aperture (i.e., as a beam-optical aperture) and as a differential pumping aperture, a more compact electron microscope can be provided that facilitates good vacuum conditions in the gun housing 10a and, hence, a good beam stability. As is schematically depicted in FIG. 1, the extractor electrode 114 with the first opening 115 may be a part of the gas separation wall between the first vacuum region 10a and the second vacuum region 10b.

As is schematically depicted in FIG. 1, the electron microscope 100 may include a second vacuum region 10b downstream of the gun housing, the second vacuum region 10b housing the condenser lens 130.

In some embodiments, the electron microscope may further include a second beam limiting aperture 132 between the condenser lens 130 and the objective lens 140. The condenser lens 130 may be configured for adjusting a beam divergence of the electron beam and thus to adjust the portion of the electron beam that propagates through the second beam limiting aperture 132. Accordingly, the excitation of the condenser lens 130 may be used to adjust the beam current of the electron beam downstream of the second beam limiting aperture 132.

Optionally, the second beam limiting aperture 132 may be arranged to act as a second differential pumping aperture. In other words, the second beam limiting aperture 132 may be arranged in a gas separation wall between the second vacuum region 10b and a third vacuum region 10c downstream of the second vacuum region 10b, such as to enable differential pumping between said regions. The vacuum conditions in the gun housing can be further improved and contamination can be further reduced. For example, the second beam limiting aperture 132 may have a diameter of 100 μm or less, particularly 50 μm or less, more particularly 20 μm or less, or even 10 μm or less.

Accordingly, as a consequence of the above differential pumping concept, the vacuum conditions in the first vacuum region 10a where the cold field emitter is placed can be further improved and an extremely low pressure of, e.g. 10⁻¹¹ mbar or less can be provided in the first vacuum region and maintained during the operation of the electron microscope. Said pressure can be maintained in the gun housing, even if the pressure in the vacuum region 10d where the specimen 16 is placed may be considerably higher, such as 10⁻⁶ mbar or more, or 10⁻⁵ mbar or more and/or 10⁻³ mbar or less, particularly a pressure between 10⁻³ mbar and 10⁻⁶ mbar.

According to some embodiments described herein, both the first opening 115 and the second beam limiting aperture 132 are beam-optical apertures, i.e. both apertures influence the shape and/or dimension of the electron beam 105 during operation. In addition, both the first opening 115 and the second beam limiting aperture 132 may be configured to act as pressure stage apertures. In other words, both apertures are not only arranged for improving the vacuum conditions in the gun housing 10a, but are also part of the beam-optical system that influences the electron beam. The first opening 115 and the second beam limiting aperture 132 can therefore also be referred to as “beam-optical pressure stage apertures” or “beam-defining pressure stage apertures”.

In some embodiments, which can be combined with other embodiments described herein, the electron microscope further includes at least one third differential pumping aperture 133 between the second differential pumping aperture and the objective lens 140. Specifically, the at least one third differential pumping aperture 133 may be arranged in a gas separation wall between the third vacuum region 10c and a fourth vacuum region 10d downstream of the third vacuum region 10c, enabling differential pumping from the gun housing 10a over the second and third vacuum regions to the fourth vacuum region 10d where the objective lens may be arranged. The vacuum conditions in the gun housing can be further improved. At least one or more beam-optical components may be arranged in the third vacuum region 10c, for example one or more of a second condenser lens, an aberration corrector, a beam separator for separating signal electrons from the electron beam and/or an electron detector for detecting signal electrons. The objective lens 140 may be arranged in the fourth vacuum region 10d (or, alternatively, in the third vacuum region, if no fourth vacuum region is provided).

A pumping port 11 for attaching a vacuum pump may be provided at each of the first vacuum region 10a, the second vacuum region 10b, the third vacuum region 10c, and the fourth vacuum region 10d (if present). The pumping port 11 may be configured for attaching a vacuum pump, such as an ion getter pump, to the respective vacuum region.

In some embodiments, which can be combined with other embodiments described herein, the emission tip 112 is arranged in the first vacuum region 10a and the condenser lens 130 is arranged in the second vacuum region 10b. An ion getter pump 13 and a non-evaporable getter (NEG) pump 14 may be provided for evacuating the first vacuum region 10a in which the emission tip 112 is arranged. For example, the ion getter pump 13 and the non-evaporable getter pump may be attached to the pumping port 11 of the first vacuum region 10a, or the ion getter pump may be arranged separate from the non-evaporable getter pump, e.g. at a separate pumping port of the first vacuum region 10a. The vacuum conditions at the position of the emission tip can be further improved.

In some embodiments, the electron microscope is a scanning electron microscope (SEM). The electron microscope may include a scan deflector 152, for example positioned close to or within the objective lens 140. Specifically, the electron microscope may be an electron beam inspection system (EBI system), particularly an SEM for high throughput electron beam inspection, e.g. of wafers or other semiconductor substrates. More specifically, the electron microscope may be a High Throughput Wafer Inspection SEM.

According to embodiments described herein, a high-performance electron microscope with a CFE electron source is provided that allows the inspection of specimens, particularly wafers and other semiconductor samples, with a high-brightness electron beam at a high resolution and with a high throughput. For example, wafers and other specimens can be quickly inspected at a high resolution. The high brightness of the electron beam can be provided and maintained, since the vacuum conditions are improved and contamination is reduced by providing and operating the first and second cleaning arrangements as described herein. Further, the high brightness is enabled due to the excellent vacuum conditions in the gun housing despite the compactness of the electron microscope, because electron-electron interactions are reduced.

According to another aspect described herein, an electron source 110 for a high-performance electron apparatus is provided, the electron source including a cold field emitter with an emission tip 112 and an extractor electrode 114 that can respectively be cleaned by first and second cleaning arrangements as described herein.

FIG. 2 is a schematic sectional view of an electron microscope 200 with an electron source 110 that includes a cold field emitter according to embodiments described herein. The electron microscope 200 of FIG. 2 may include some feature or all the features of the electron microscope 100 of FIG. 1, such that reference can be made to the above explanations, which are not repeated here.

Specifically, the electron microscope 200 includes a cold field emitter with an emission tip 112 that can be cleaned by heating—in a first cleaning mode—with the first cleaning arrangement 121 and with an extractor electrode 114 that can be cleaned by heating—in a second cleaning mode—with the second cleaning arrangement 122.

The first opening 115 in the extractor electrode 114 may act as a beam limiting aperture for shaping the electron beam and may optionally additionally act as a differential pumping aperture that enables differential pumping between the first vacuum region 10a and the second vacuum region 10b.

According to some embodiments, which can be combined with other embodiments described herein, the condenser lens 130 is a magnetic condenser lens. In particular, the magnetic condenser lens may include a first inner pole piece and a first outer pole piece, wherein a first axial distance (D1) between the emitter tip 112 and the first inner pole piece is larger than a second axial distance (D2) between the emitter tip 112 and the first outer pole piece. Such a magnetic lens whose outer pole piece protrudes further toward the electron source than the inner pole piece has an axially extending gap between the pole pieces and may therefore also be referred to as an “axial gap lens”. An axial gap magnetic lens may generate a magnetic field which may extend into a region beyond the axial gap, i.e. axially beyond the outer pole piece and toward the electron source. In other words, the axial gap condenser lens may be an immersion lens and provide a magnetic interaction region that extends toward the electron source, such that the collimation effect of the condenser lens may act on the electron beam 105 close to or even inside the electron source 110. A more compact electron microscope can be provided and negative effects of electron-electron interaction can be reduced.

In some embodiments, the first axial distance (D1) between the emission tip 112 and the first inner pole piece of the condenser lens is 20 mm or less, particularly 15 mm or less. In some embodiments, the second axial distance (D2) between the emission tip 112 and the condenser lens is 15 mm or less, in some embodiments 8 mm or less.

The acceleration section of the electron microscope for accelerating the electrons to an energy of 5 keV or more, particularly 10 keV or more, may partially overlap with the magnetic interaction region of the condenser lens, which reduces the overall beam propagation distance within the electron microscope.

According to some embodiments, the objective lens 140 is a magnetic objective lens having a second inner pole piece and a second outer pole piece, and a third axial distance (D3) between the second inner pole piece and the sample stage 18 is larger than a fourth axial distance (D4) between the second outer pole piece and the sample stage 18. In particular, the magnetic objective lens may be an axial gap lens whose outer pole piece projects further toward the sample stage 18 than the inner pole piece, such that an axial gap is formed between the ends of the outer and inner pole pieces. The magnetic interaction region provided by the magnetic objective lens may extend axially beyond the pole pieces of the magnetic objective lens toward the specimen 16 that may be placed on the sample stage 18. This allows the objective lens to have a short focal length and to be placed close to the sample stage 18.

In some implementations, the distance between the objective lens 140 and the sample stage 18 (i.e., the fourth axial distance (D4)) may be 20 mm or less, particularly 10 mm or less, more particularly 5 mm or less. Specifically, the focal length of the objective lens 140 may be 10 mm or less, or even 5 mm or less. In some embodiments, the third axial distance (D3) between the sample stage 18 and the second inner pole piece of the objective lens 140 is larger than the fourth axial distance (D4), particularly 30 mm or less, more particularly 10 mm or less.

In some embodiments, the condenser lens 130 and the objective lens 140 may both be axial gap lenses that may be arranged symmetrically with respect to each other along the optical axis A. Specifically, the condenser lens 130 may have an axial gap that is open toward the electron source 110, and the objective lens 140 may have an axial gap that is open toward the specimen, both lenses being configured as immersion lenses that face into opposite directions. Using corresponding lens types as the condenser lens and the objective lens may lead to a compact electron microscope that is suitable for providing a small beam probe on the specimen and hence a good resolution.

Details of the first cleaning arrangement 121, the second cleaning arrangement 122, and the differential pumping are described with respect to the electron microscope 100 of FIG. 1 and are not repeated here.

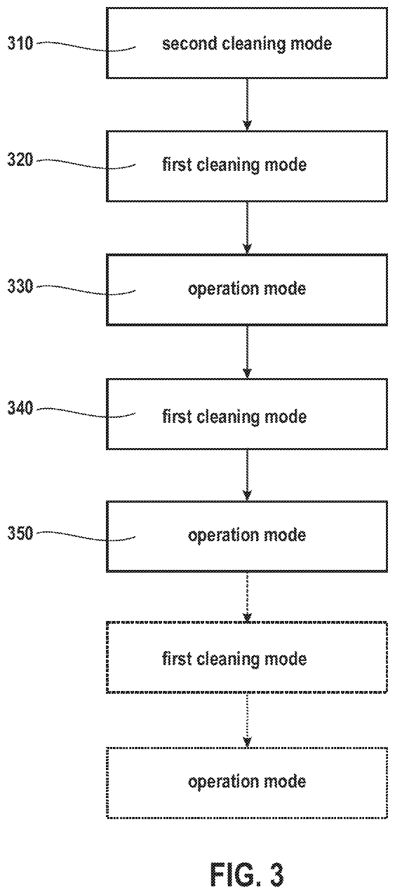

FIG. 3 shows a flow diagram of a method of operating an electron microscope according to embodiments described herein.

The electron microscope may have a gun housing that houses the electron source with the cold field emitter and that provides a first vacuum region. A second vacuum region may be arranged downstream of the first vacuum region along the optical axis, and optionally a third or even further vacuum regions may be arranged downstream of the second vacuum region along the optical axis, which can be differentially pumped. The first vacuum region and the second vacuum region may be separated by a first gas separation wall having a first differential pumping aperture provided therein, and the second vacuum region and the third vacuum region may be separated by a second gas separation wall having a second differential pumping aperture provided therein.

The electron source of the electron microscope includes a cold field emitter with an emission tip and an extractor electrode for extracting an electron beam from the cold field emitter for propagation along an optical axis A.

In boxes 310 and 320 of FIG. 3, the electron microscope is prepared for operation in two cleaning stages, for example before the very first operation of the electron microscope, or after flooding of the interior of the electron microscope with air, e.g. during servicing or maintenance.

In box 310, the electron microscope is set in a second cleaning mode, in which the extractor electrode of the electron source is cleaned by heating the extractor electrode, particularly to a temperature of 500° C. or more, more particularly to a temperature between 600° C. and 800° C. Specifically, an area of the extractor electrode that surrounds the first opening through which the electron beam propagates during operation is heated to a temperature between 600° C. and 800° C.

In the second cleaning mode, a current may flow through a second heater that is positioned adjacent to the extractor electrode for heating the extractor electrode to the temperature above 500° C., particularly to the temperature between 600° C. and 800° C. The second heater may be a heating wire 126 that is arranged close to the first opening and that may optionally at least partially extend around the first opening upstream of the extractor electrode. In some embodiments, the heating wire 126 may be a tantalum wire or tantalum filament.

The current to be applied in the second cleaning mode can be determined in a preceding calibration stage.

Optionally, in the second cleaning mode, the suppressor electrode and/or the extractor electrode may be set on one or more predetermined electrical potentials, which may help to direct thermal electrons emitted by the heating wire toward the extractor electrode and/or away from the emission tip.

In box 320, the electron microscope is set in a first cleaning mode, in which the emission tip of the cold field emitter is cleaned by heating the emission tip, particularly to a temperature of 1500° C. or more, particularly 2000° C. or more, or even 2000 K or more.

In the first cleaning mode, a current may flow through a heating filament to which the emission tip is bonded, particularly to a V-shaped heating filament, for heating the emission tip to a temperature above 2000° C. Particles that are adhered to the emission tip can be evaporated and the emission surface can be cleaned. The current to be applied in the first cleaning mode can be determined in a preceding calibration stage.

Optionally, in the first cleaning mode, the suppressor electrode and/or the extractor electrode may be set on one or more predetermined electrical potentials, particularly on a high voltage relative to the emission tip, which may facilitate the maintenance of a sharp emission tip.

After cleaning in the first and second cleaning modes, the electron microscope may be set in an operation mode that is illustrated by box 330. In the operation mode, an electron beam is extracted from the cold field emitter for propagation along the optical axis, and the electron beam is shaped by propagating through the first opening that may be provided in the extractor electrode. The electron beam is then collimated by a condenser lens downstream of the electron source, i.e. the divergence of the electron beam is reduced. In particular, the divergence of the electron beam may be adjusted by adjusting the excitation of the condenser lens. The collimated electron beam is then focused onto a specimen with the objective lens.

In the operation mode, the electrons of the electron beam may be accelerated in an acceleration section to an energy of 5 keV or more, particularly 10 keV or more, wherein the acceleration section is arranged upstream of and/or at least partially overlapping with the condenser lens. For example, a first part of the acceleration section may extend between the emission tip and the extractor electrode, the extractor electrode being set on a high voltage relative to the emission tip. A second part of the acceleration section may extend downstream of the electron source, e.g. between the extractor electrode and an anode that may be set on a high voltage relative to the extractor electrode. The anode may be arranged close to or inside the condenser lens. Accordingly, the acceleration section may overlap with the magnetic interaction region provided by the condenser lens.

In the operation mode, the electron beam may be collimated with the condenser lens. The condenser lens may be a magnetic lens having a first inner pole piece and a first outer pole piece, wherein a first axial distance between the emission tip and the first inner pole piece may be larger than a second axial distance between the emission tip and the first outer pole piece. Specifically, the condenser lens may be an axial gap lens, i.e. the first outer pole piece of the condenser lens may protrude further toward the electron source than the first inner pole piece of the condenser lens.

In the operation mode, the electrons of the electron beam may be decelerated in a deceleration section to a landing energy of 3 keV or less, particularly 1 keV or less, wherein the deceleration section is downstream of or at least partially overlapping with the objective lens. For example, a potential difference may be applied between a first electrode arranged close to or inside the objective lens and a proxy electrode arranged close to the specimen or to the specimen itself. Accordingly, the deceleration section may overlap with the magnetic interaction region provided by the objective lens.

The electron beam may be focused onto the specimen, and the generated signal electrons may be accelerated toward and through the objective lens and may be detected by one or more electron detectors (not shown in the figures) for inspecting the specimen, e.g. for generating an image of the specimen.

In some embodiments, which can be combined with other embodiments described herein, the emission tip is arranged in a first vacuum region and the condenser lens is arranged in a second vacuum region downstream of the first vacuum region. The first opening in the extractor electrode may act as a differential pumping aperture between the first vacuum region and the second vacuum region. The method may include differentially pumping the first vacuum region and the second vacuum region.

Optionally, a third vacuum region may be provided downstream of the second vacuum region, and a second differential pumping aperture may be provided in a gas separation wall therebetween. The method may further include differentially pumping the first, second, and third vacuum region, and optionally at least one further vacuum region downstream of the third vacuum region.

As is schematically illustrated by box 340 in FIG. 3, the electron microscope may switch back to the first cleaning mode after a predetermined time in the operation mode of box 330, e.g. after about one hour of operation. The emission tip may be cleaned in the first cleaning mode, such that a stable electron beam can be ensured. In box 350, the electron microscope may switch back to operation.

In some embodiments, the method includes switching from the operation mode to the first cleaning mode after a predetermined period of time in the operation mode, e.g., after about one hour of operation, respectively. In particular, the electron microscope may automatically switch to the first cleaning mode after predetermined intervals of operation of, for example, one hour or more and three hours or less, respectively. Switching to the first cleaning mode after predetermined intervals of operation can enable a continually stable and high-brightness electron beam in the operation mode.

The second cleaning mode may be conducted less frequently, for example only after flooding of the gun housing with air and/or in predetermined servicing intervals that may be longer than a month and/or in case the electron beam shows undesired instabilities or a reduced brightness.

In particular, the following embodiments are described herein:

Embodiment 1: An electron microscope (100), comprising: an electron source (110), comprising: a cold field emitter with an emission tip (112); an extractor electrode (114) for extracting an electron beam (105) from the cold field emitter for propagation along an optical axis (A), the extractor electrode having a first opening (115) configured as a first beam limiting aperture; a first cleaning arrangement (121) for cleaning the emission tip (112) by heating the emission tip; and a second cleaning arrangement (122) for cleaning the extractor electrode (114) by heating the extractor electrode; the electron microscope further comprising: a condenser lens (130) for collimating the electron beam downstream of the electron source; and an objective lens (140) for focusing the electron beam onto a specimen.
In some embodiments, the emission tip is a tungsten tip, particularly a tungsten single crystal with (3,1,0) orientation.
Embodiment 2: The electron microscope according to embodiment 1, wherein the first cleaning arrangement (121) comprises a heating filament (125) in thermal contact with the emission tip, the emission tip being attached to or bonded to the heating filament.
The first cleaning arrangement may be a flash cleaning device configured to clean the emission tip by heating the emission tip, particularly in regular intervals, e.g. after a predetermined time of operation, respectively. The emission tip may be heated to a temperature above 1000° C., particularly above 2000° C.
In some embodiments, the heating filament is a V-shaped heating wire, the emission tip being bonded to the kink portion of the V-shaped heating wire.
In some embodiments, the heating filament is a metal filament, particularly a tungsten filament, and the emission tip is a tungsten tip.
Embodiment 3: The electron microscope according to embodiment 1 or 2, wherein the second cleaning arrangement comprises a second heater, particularly a heating wire (126), positioned adjacent to the extractor electrode (114). The second heater may be configured to be heated to a temperature of 1500° C. or more, particularly 2000° C. or more, specifically by allowing an electric current to flow through the second heater.
Embodiment 4: The electron microscope according to embodiment 3, wherein the heating wire is arranged to at least partially surround the first opening (115) of the extractor electrode.
Embodiment 5: The electron microscope according to embodiment 3 or 4, wherein the heating wire (126) comprises or is made of tantalum.
Embodiment 6: The electron microscope according to any of embodiments 1 to 5, comprising a cleaning controller (128) that is configured to allow, in a first cleaning mode, a current to flow through a heating filament (125) that is in thermal contact with the emission tip for heating the emission tip to a temperature above 1500° C. Alternatively or additionally, a cleaning controller is configured to allow, in a second cleaning mode, a current to flow through a heating wire (126) of the second cleaning arrangement for at least one of heating the extractor electrode at least partially to a temperature above 500° C. and causing electron stimulated desorption on a surface of the extractor electrode.
In particular, an area of the extractor electrode that surrounds the first opening is heated to a temperature above 500° C. in the second cleaning mode, particularly for causing thermal outgassing of the extractor electrode.
Embodiment 7: The electron microscope according to any of embodiments 1 to 6, wherein a distance between the emission tip (112) and the first opening (115) of the extractor electrode (114) along the optical axis is 5 mm or less, particularly 1 mm or less.
Embodiment 8: The electron microscope according to any of embodiments 1 to 7, wherein the condenser lens (130) is a magnetic condenser lens having a first inner pole piece and a first outer pole piece, wherein a first axial distance (D1) between the emission tip and the first inner pole piece is larger than a second axial distance (D2) between the emission tip and the first outer pole piece.
In particular, the magnetic condenser lens may be an axial gap lens.
In some embodiments, the first axial distance (D1) between the emission tip and the first inner pole piece is 20 mm or less, particularly 15 mm or less. In some embodiments, the second axial distance (D2) between the emission tip and the first inner pole piece is 15 mm or less, or even 8 mm or less.
Embodiment 9: The electron microscope according to any of embodiments 1 to 8, wherein the objective lens (140) is a magnetic objective lens having a second inner pole piece and a second outer pole piece, wherein a third axial distance between the second inner pole piece and a sample stage is larger than a fourth axial distance between the second outer pole piece and the sample stage.
In particular, the magnetic objective lens may be an axial gap lens.
In some embodiments, the magnetic condenser lens and the magnetic objective lens may be arranged approximately symmetrically with respect to each other along the optical axis.
Embodiment 10: The electron microscope according to any of embodiments 1 to 9, comprising an acceleration section for accelerating the electron beam to an energy of 5 keV or more, the acceleration section being upstream of or at least partially overlapping with the condenser lens; and/or a deceleration section for decelerating the electron beam from the energy of 5 keV or more to a landing energy of 3 keV or below, the deceleration section being downstream of or at least partially overlapping with the objective lens.
Embodiment 11: The electron microscope according to any of embodiments 1 to 10, wherein the first opening (115) is arranged to act as a first differential pumping aperture.
Embodiment 12: The electron microscope according to any of embodiments 1 to 11, further comprising a second beam limiting aperture (132) between the condenser lens (130) and the objective lens (140), the second beam limiting aperture (132) arranged to act as a second differential pumping aperture.
Embodiment 13: The electron microscope according to embodiment 12, further comprising at least one third differential pumping aperture (133) between the second differential pumping aperture and the objective lens.
Embodiment 14: The electron microscope according to any of embodiments 1 to 13, wherein the emission tip (112) is arranged in a first vacuum region (10a) and the condenser lens (130) is arranged in a second vacuum region (10b), the electron microscope comprising an ion getter pump (13) and a non-evaporable getter pump (14) for pumping the first vacuum region
Embodiment 15: The electron microscope according to any of embodiments 1 to 14, further comprising a scan deflector, wherein the electron microscope is configured as a scanning electron microscope (SEM) for high throughput wafer inspection.
Embodiment 16: An electron source of the electron microscope according to any of the embodiments described herein.
Embodiment 17: A method of operating an electron microscope having an electron source with a cold field emitter, comprising: in a first cleaning mode, cleaning an emission tip of the cold field emitter by heating the emission tip; in a second cleaning mode, cleaning an extractor electrode of the electron source by heating the extractor electrode; and in an operation mode: extracting an electron beam from the cold field emitter for propagation along an optical axis (A), the electron beam being shaped by a first opening provided in the extractor electrode; collimating the electron beam with a condenser lens; and focusing the electron beam onto a specimen with an objective lens.
Embodiment 18: The method of embodiment 17, wherein in the first cleaning mode a current flows through a heating filament to which the emission tip is bonded for heating the emission tip to a temperature above 1500° C.
Embodiment 19: The method of embodiment 17 or 18, wherein in the second cleaning mode a current flows through a second heater, particularly through a heating wire (126), positioned adjacent to the extractor electrode for heating the extractor electrode to a temperature above 500° C.
Embodiment 20: The method of any of embodiments 17 to 19, wherein in the second cleaning mode a current flows through a heating wire positioned adjacent to the extractor electrode to cause thermal emission of electrons from the heating wire for cleaning of the extractor electrode by at least one of electron stimulated desorption and thermal outgassing. In some embodiments, the heating wire is heated to temperatures of 1500° C. or more, particularly 2000° C. or more.
Embodiment 21: The method of any of embodiments 17 to 20, comprising switching from the operation mode to the first cleaning mode after a predetermined period of time in the operation mode, particularly automatically switching to the first cleaning mode after predetermined intervals of operation.
Embodiment 22: The method of any of embodiments 17 to 21, wherein the emission tip is arranged in a first vacuum region and the condenser lens is arranged in a second vacuum region downstream of the first vacuum region, the first opening acting as a differential pumping aperture between the first vacuum region and the second vacuum region, the method comprising differentially pumping the first vacuum region and the second vacuum region, and optionally a third vacuum region arranged downstream of the second vacuum region via a second differential pumping aperture arranged between the second vacuum region and the third vacuum region.
Embodiment 23: The method of any of embodiments 17 to 22, further comprising, in the operation mode, any one or more of the following: (i) accelerating electrons of the electron beam in an acceleration section to an energy of 5 keV or more, the acceleration section being upstream of or at least partially overlapping with the condenser lens; (ii) collimating the electron beam with the condenser lens that has a first inner pole piece and a first outer pole piece, wherein a first axial distance between the emission tip and the first inner pole piece is larger than a second axial distance between the emission tip and the first outer pole piece; and/or (iii) decelerating electrons of the electron beam in a deceleration section to a landing energy of 3 keV or below, the deceleration section being downstream of or at least partially overlapping with the objective lens.
In some embodiments, the electrons of the electron beam are accelerated in the acceleration section to an energy of at least 10 keV, particularly at least 15 keV, more particularly at least 30 keV.
In some embodiments, the electrons of the electron beam are decelerated in the deceleration section to a landing energy of 2 keV or less, particularly 1 keV or less.

It is to be understood that each of the claims that follow herebelow may refer back to one or more precedent claims, and such embodiments that include the features of an arbitrary subset of the claims are encompassed by the present disclosure. While the foregoing is directed to embodiments, other and further embodiments may be devised without departing from the basic scope, and the scope thereof is determined by the claims that follow.

1. An electron microscope, comprising:
an electron source, comprising:
a cold field emitter with an emission tip;
an extractor electrode for extracting an electron beam from the cold field emitter for propagation along an optical axis, the extractor electrode having a first opening configured as a first beam limiting aperture;
a first cleaning arrangement for cleaning the emission tip by heating the emission tip; and
a second cleaning arrangement for cleaning the extractor electrode by heating the extractor electrode;
a condenser lens for collimating the electron beam downstream of the electron source; and
an objective lens for focusing the electron beam onto a specimen.

2. The electron microscope according to claim 1, wherein the first cleaning arrangement comprises a heating filament in thermal contact with the emission tip, the emission tip being attached to or bonded to the heating filament.

3. The electron microscope according to claim 1, wherein the second cleaning arrangement comprises a heating wire positioned adjacent to the extractor electrode and configured to be heated to a temperature of 1500° C. or more.

4. The electron microscope according to claim 3, wherein the heating wire is arranged to at least partially surround the first opening of the extractor electrode.

5. The electron microscope according to claim 3, wherein the heating wire comprises or is made of tantalum.

6. The electron microscope according to claim 1, comprising a cleaning controller
configured to allow, in a first cleaning mode, a current to flow through a heating filament that is in thermal contact with the emission tip for heating the emission tip to a temperature above 1500° C., and/or
configured to allow, in a second cleaning mode, a current to flow through a heating wire of the second cleaning arrangement for at least one of heating the extractor electrode at least partially to a temperature above 500° C. and causing electron stimulated desorption on a surface of the extractor electrode.

7. The electron microscope according to claim 1, wherein a distance between the emission tip and the first opening of the extractor electrode is 5 mm or less, particularly 1 mm or less.

8. The electron microscope according to claim 1, wherein the condenser lens is a magnetic condenser lens having a first inner pole piece and a first outer pole piece, and a first axial distance between the emission tip and the first inner pole piece is larger than a second axial distance between the emission tip and the first outer pole piece.

9. The electron microscope according to claim 1, wherein the objective lens is a magnetic objective lens having a second inner pole piece and a second outer pole piece, and a third axial distance between the second inner pole piece and a sample stage is larger than a fourth axial distance between the second outer pole piece and the sample stage.

10. The electron microscope according to claim 1, comprising an acceleration section for accelerating the electron beam to an energy of 5 keV or more, the acceleration section being upstream of or at least partially overlapping with the condenser lens; and
a deceleration section for decelerating the electron beam from the energy of 5 keV or more to a landing energy of 2 keV or below, the deceleration section being downstream of or at least partially overlapping with the objective lens.

11. The electron microscope according to claim 1, wherein the first beam limiting aperture is arranged to act as a first differential pumping aperture.

12. The electron microscope according to claim 1, further comprising a second beam limiting aperture between the condenser lens and the objective lens, the second beam limiting aperture arranged to act as a second differential pumping aperture.

13. The electron microscope according to claim 1, wherein the emission tip is arranged in a first vacuum region and the condenser lens is arranged in a second vacuum region, the electron microscope comprising an ion getter pump and a non-evaporable getter pump for pumping the first vacuum region.

14. The electron microscope according to claim 1, further comprising a scan deflector, wherein the electron microscope is configured as a scanning electron microscope (SEM) for high throughput wafer inspection.

15. An electron source for an electron microscope, comprising:
a cold field emitter with an emission tip;
an extractor electrode for extracting an electron beam from the cold field emitter for propagation along an optical axis;
a first cleaning arrangement for cleaning the emission tip by heating the emission tip; and
a second cleaning arrangement for cleaning the extractor electrode by heating the extractor electrode.

16. A method of operating an electron microscope having an electron source with a cold field emitter, comprising:
in a first cleaning mode, cleaning an emission tip of the cold field emitter by heating the emission tip;
in a second cleaning mode, cleaning an extractor electrode of the electron source by heating the extractor electrode; and
in an operation mode:
extracting an electron beam from the cold field emitter for propagation along an optical axis, the electron beam being shaped by a first opening provided in the extractor electrode;
collimating the electron beam with a condenser lens; and
focusing the electron beam onto a specimen with an objective lens.

17. The method according to claim 16, wherein in the first cleaning mode a current flows through a heating filament to which the emission tip is bonded for heating the emission tip to a temperature above 1500° C.

18. The method according to claim 16, wherein in the second cleaning mode a current flows through a heating wire positioned adjacent to the extractor electrode to cause thermal emission of electrons from the heating wire for cleaning of the extractor electrode by at least one or both of electron stimulated desorption and thermal outgassing.

19. The method according to claim 16, comprising switching from the operation mode to the first cleaning mode after a predetermined period of time in the operation mode, particularly automatically switching to the first cleaning mode in predetermined intervals of operation.

20. The method according to claim 16, wherein the emission tip is arranged in a first vacuum region and the condenser lens is arranged in a second vacuum region downstream of the first vacuum region, the first opening acting as a differential pumping aperture between the first vacuum region and the second vacuum region, the method comprising:
differentially pumping the first vacuum region and the second vacuum region, and optionally a third vacuum region arranged downstream of the second vacuum region via a second differential pumping aperture arranged between the second vacuum region and the third vacuum region.

21. The method according to claim 16, further comprising in the operation mode:
accelerating electrons of the electron beam in an acceleration section to an energy of 5 keV or more, the acceleration section being upstream of or at least partially overlapping with the condenser lens;
collimating the electron beam with the condenser lens that has a first inner pole piece and a first outer pole piece, wherein a first axial distance between the emission tip and the first inner pole piece is larger than a second axial distance between the emission tip and the first outer pole piece; and
decelerating the electrons of the electron beam in a deceleration section to a landing energy of 3 keV or below, the deceleration section being downstream of or at least partially overlapping with the objective lens.
